(19) United States
(12) Patent Application Publication
(10) Pub. No.: US 2009/0167944 A1
(43) Pub. Date: Jul. 2, 2009

(54) Video-signal receiving apparatus and method

(75) Inventors: Ching-Yuan Cheng, Hsinchu City (TW); Chih-Ching Han, Hsinchu City (TW)

Correspondence Address: RABIN & Berdo, PC, 1101 14TH STREET, NW, SUITE 500, WASHINGTON, DC, 20005, US

(73) Assignee: NOVATEK MICROELECTRONICS CORP., Hsinchu (TW)

(21) Appl. No.: 12/068,801

(22) Filed: Feb. 12, 2008

(30) Foreign Application Priority Data
Dec. 28, 2007 (TW) 096150967

(51) Int. Cl. H03L 7/00

(52) U.S. Cl. 348/536

(57) ABSTRACT

A video-signal receiving method is provided. First, receive an analog video signal, wherein the analog video signal comprises a specific video signal and a synchronization signal. Next, at least perform an analog-to-digital conversion on the synchronization signal of the analog video signal according to a sampling signal to generate a digital signal. Then, receive the digital signal and decoding the digital signal to obtain a digital synchronization signal corresponding to the synchronization signal. Afterward, adjust a phase of the sampling signal according to the digital synchronization signal.

This application claims the benefit of Taiwan application Serial No. 096150967, filed Dec. 28, 2007, the subject matter of which is incorporated herein by reference.

### BACKGROUND OF THE INVENTION

1. Field of the Invention

The invention relates in general to a video-signal receiving apparatus and method, and more particularly to a video-signal receiving apparatus and method for generating video frames with better quality.

2. Description of the Related Art

In the process of video-signal transmission, the video signal source normally converts the video signal into an analog video signal by using a digital-to-analog converter (DAC) and then outputs the analog video signal to a video-signal receiving apparatus via a cable.

For example, the above-mentioned video signal source is a video box or a digital video disk (DVD) player. In terms of the DVD player, when a DVD disc is decoded to obtain the video data stored therein, the decoded video signal (usually a digital signal) will be converted into an analog video signal by a DAC and the obtained analog video signal is then transmitted via the cable to the video-signal receiving apparatus.

In terms of the video-signal receiving apparatus, an analog-to-digital converter (ADC) is used to convert the received analog video signal into a digital video signal according to a sampling signal. Generally speaking, the frequency of the sampling signal is related to the frequency of a clock signal used by the video signal source (for example, the DAC inside the video signal source). Then, the video-signal receiving apparatus can perform image processing on the digital video signal and transmits the processed digital video signal to the post-end display device for display.

In the video-signal receiving apparatus, the sampling signal must have an optimum sampling phase in order that the ADC can correctly convert the analog video signal into the digital video signal. However, the phase of the video signal received by the video-signal receiving apparatus may change because of the imperfect characteristics of the video signal source or the cable. In the prior art, the phase of the sampling signal is set to be a constant value. As a result, the phase of the sampling signal does not change in accordance with the video signal and thus the optimum video frame cannot be obtained by this design.

Therefore, the video-signal receiving apparatus has to automatically adjust the phase of the sampling signal to obtain the optimum video frame. Referring to FIG. 1, a block diagram of a conventional video-signal receiving apparatus is shown. The video-signal receiving apparatus 100 includes an ADC 110, a digital image processor 120 and a phase adjustment device 130. The ADC 110 converts an analog video signal AS into a digital video signal DS according to a sampling signal SS. The digital image processor 120 performs an image processing on the digital video signal DS and obtains video information VI in the digital video signal DS. The phase adjustment device 130 adjusts the phase of the sampling signal SS according to the video information VI.

However, the above-mentioned adjustment mechanism has the issue of being limited to the feature of the video information VI because it uses the video information VI as a basis for the adjustment of the sampling signal SS. For example, when the digital video signal DS corresponds to a white frame or single-color frame, the corresponding video signal VI would be too simple to provide information for phase adjustment, and consequently, the phase adjustment device 130 cannot obtain the optimum sampling phase. On the other hand, when the digital video signal DS is a high-quality dynamic video signal such as HDTV, the phase adjustment device 130 can hardly process the excessively-large amount of video information VI in the digital video signal DS, and thus cannot obtain the optimum sampling phase as well.

### SUMMARY OF THE INVENTION

The invention is directed to a video-signal receiving apparatus and method. The phase of the sampling signal can be automatically adjusted without referring to the video information and a better analog-to-digital conversion can be performed on the received analog video signal according to the adjusted sampling signal to obtain the video frame of better quality.

According to a first aspect of the present invention, a video-signal receiving apparatus is provided. The video-signal receiving apparatus comprises an ADC, a digital image processor and a phase adjustment device. The ADC is for receiving an analog video signal. The analog video signal comprises a specific video signal and a synchronization signal, and the ADC at least converts the synchronization signal of the analog video signal into a digital signal according to a sampling signal. The digital image processor is coupled to the ADC for receiving the digital signal and decoding the digital signal to obtain a digital synchronization signal corresponding to the synchronization signal. The phase adjustment device is coupled to the digital image processor and the ADC for adjusting a phase of the sampling signal according to the digital synchronization signal.

According to a second aspect of the present invention, a video-signal receiving method is provided. The video-signal receiving method comprises receiving an analog video signal, wherein the analog video signal comprises a specific video signal and a synchronization signal; at least performing an analog-to-digital conversion on the synchronization signal of the analog video signal according to a sampling signal to generate a digital signal; receiving the digital signal and decoding the digital signal to obtain a digital synchronization signal corresponding to the synchronization signal; and adjusting a phase of the sampling signal according to the digital synchronization signal.

The invention will become apparent from the following detailed description of the preferred but non-limiting embodiments. The following description is made with reference to the accompanying drawings.

### BRIEF DESCRIPTION OF THE DRAWINGS

FIG. 1 is a block diagram of a conventional video-signal receiving apparatus.

FIG. 2 is a block diagram of a video-signal receiving apparatus according to a preferred embodiment of the invention.

FIG. 3 is a waveform diagram of one example of the luminance signal (Y).

FIG. 4 is a schematic partial diagram of the sampling of a synchronization signal according to the preferred embodiment of the invention.

FIG. 5 is a flow chart of the video-signal receiving method according to the preferred embodiment of the invention.

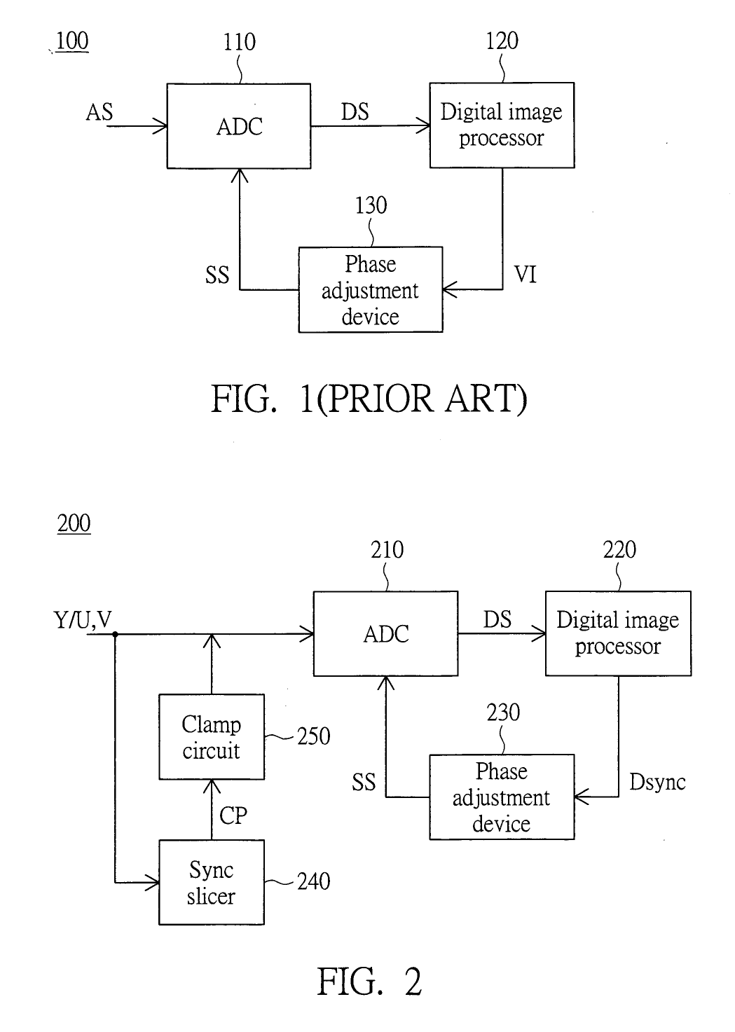

### DETAILED DESCRIPTION OF THE INVENTION

The invention is directed to a video-signal receiving apparatus and method. The phase of the sampling signal can be adjusted and the analog video signal can be correctly converted into a digital signal according to the adjusted sampling signal to improve the display quality of video frames.

Referring to FIG. 2, a block diagram of a video-signal receiving apparatus according to a preferred embodiment of the invention is shown. A video-signal receiving apparatus 200 includes an ADC 210, a digital image processor 220, a phase adjustment device 230, a sync slicer 240 and a clamp circuit 250. The ADC 210 is used for receiving a composite signal. The composite signal includes a luminance signal (Y) and a chrominance signal (U, V). The ADC 210 converts the luminance signal (Y) into a digital signal DS according to a sampling signal SS.

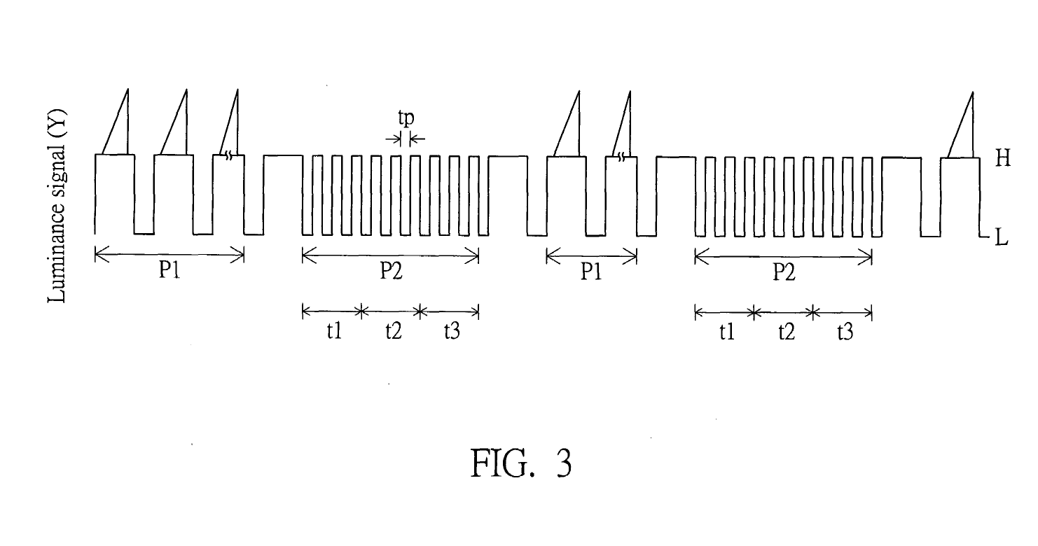

Referring to FIG. 3, a waveform diagram of one example of the luminance signal (Y) is shown. The luminance signal (Y) includes a specific video signal and a synchronization signal. The luminance signal (Y) corresponds to the specific video signal during a number of first periods P1. The so-called specific video signal corresponds to frame information. For example, in each of the first periods P1, the specific video signal corresponds to luminance information of a picture frame. Besides, the luminance signal (Y) corresponds to the synchronization signal during a number of second periods P2, and at least one of the second periods P2 is located between two adjacent first periods P1. The frequency of the sampling signal SS is an integral multiplier of the frequency of the synchronization signal.

In FIG. 3, each of the second periods P2 includes a pre-equalization period t1, a broad-pulse period t2 and post-equalization period t3, which complies with the specification of a normal composite signal. In each of the second periods P2, the high and low voltage levels of the synchronization signal are constant values. The synchronization signal can be used for determining the video specification of the composite signal, such as 480i, 480p or high-resolution television signal HDTV.

Furthermore, a pulse-edge of the synchronization signal includes the relevant information of a clock signal of a video signal source. That is, the pulse-edge of the synchronization signal substantially corresponds to a pulse-edge of the clock signal of the video signal source. That is because the video signal source generates the video signal for output according to a clock signal of the DAC. Therefore, the generated video signal (synchronization signal) is theoretically corresponding to the clock signal of the DAC.

Following that, the digital image processor 220 receives the digital signal DS and decodes the digital signal DS to obtain a digital video signal and a digital synchronization signal Dsync, wherein the digital video signal is corresponding to the above-mentioned specific video signal, and the digital synchronization signal is corresponding to the above-mentioned synchronization signal. Owing that the edge of the synchronization substantially includes the relevant information of the clock signal of the video signal source, the phase adjustment device 230 can adjust a sampling phase of the sampling signal SS to the optimum sampling phase according to the digital synchronization signal Dsync. In this way, the ADC 210 correctly converts the luminance signal (Y) into the digital signal DS according to the adjusted sampling signal SS. Besides, the ADC 210 also correctly converts the chrominance signal (U, V) into a digital signal for the post-end digital image processor 220 according to the adjusted sampling signal SS in order to obtain the video frame with better display quality.

It is noted that the invention uses the synchronization signal as a basis for phase adjustment of the sampling signal, which has an advantage that the synchronization signal has a specific pattern and does not change along with the video information. Therefore, even if the video information is a high-quality frame or a single-color frame, the phase adjustment device 230 of the invention can determine whether the present phase of the sampling signal is a preferred phase according to the digital synchronization signal Dsync, thereby preventing the drawback of the prior art.

The phase adjustment device 230 substantially determines whether the difference values between adjacent digital values of the digital synchronization signal Dsync are located between an upper threshold value and a lower threshold value. If yes, the phase adjustment device 230 adjusts the phase of the sampling signal SS, and if no, the phase adjustment device 230 maintains the phase of the sampling signal SS. In the following description, the synchronization signal of the luminance signal (Y) in a period tp is taken as an example for illustration.

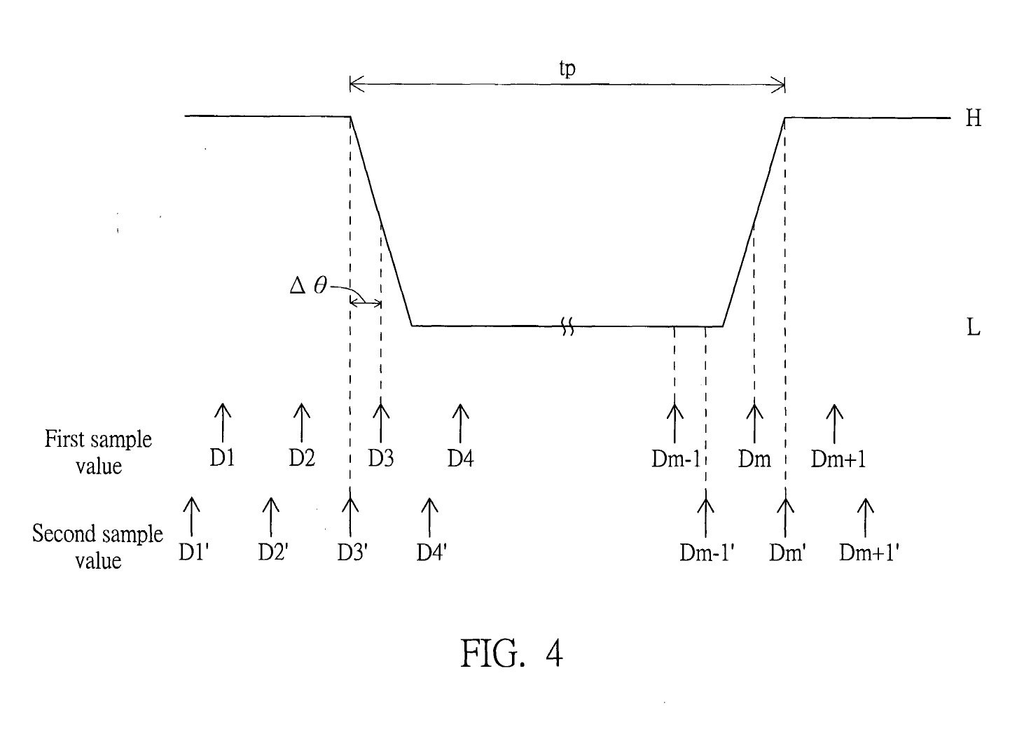

Referring to FIG. 4, a schematic partial diagram of the sampling of a synchronization signal according to the preferred embodiment of the invention is shown. The pulse-edge of the synchronization signal may have a slope after transmitted via a cable. It is noted that theoretically, if the sampling signal SS has the optimum phase, the sampling point of the ADC 210 will not fall in the portion of the synchronization signal within the slope (i.e. a transition portion of the synchronization signal). In other words, if the sampling signal SS has the optimum phase, the result of the ADC 210 sampling the synchronization signal represents the data carried by the synchronization signal (a high or low voltage level) instead of the value of the signal in a transition state (this value is located between the high and low voltage levels). Therefore, by applying the above-mentioned feature, the invention determines whether the phase of the sampling signal SS is a preferred sample value according to the sampling result (the digital synchronization signal Dsync) of the ADC 210 sampling the synchronization signal.

Continuously referring to FIG. 4, the upper threshold value is a difference between the high voltage level (H) and the low voltage level (L), and the lower threshold value is 0. First, the ADC 210 performs a first sampling operation on the synchronization signal of the luminance signal (Y) according to the sampling signal SS to obtain a number of first sample values D1, D2, D3, D4, . . . , Dm−1, Dm, Dm+1, . . . and so on. The difference values between the first sample values D2 and D3 and between the first sample values D3 and D4 are located between the upper threshold value and the lower threshold value, and the difference values between the first sample values Dm−1 and Dm and between the first sample values Dm and Dm+1 are also located between the upper threshold value and the lower threshold value, which represents that some sample values come from a sampling result of the signal in a transition state. Therefore, the phase adjustment device 230 determines the original sampling phase is not the optimum sampling phase.

Afterwards, the phase adjustment device 230 adjusts the sampling phase of the sampling signal SS by a phase difference Δθ. Then, the ADC 210 performs the second sampling operation on the synchronization signal of the luminance signal (Y) according to the adjusted sampling signal SS to obtain a number of second sample values D1′, D2′, D3′, D4′, . . . , Dm−1′, Dm′, Dm+1′, . . . and so on. The difference values between the adjacent second sample values are either one of the upper threshold value and the lower threshold value, which matches the above-mentioned feature. Therefore, the phase adjustment device 230 determines the sampling phase of the adjusted sampling signal is the optimum one and maintains the sampling phase of the adjusted sampling signal SS. Besides, owing that the synchronization signals may vary due to different video specifications, the upper threshold value and lower threshold value can be selected to form a looser limitation. In the embodiment, the upper threshold value is substantially an average of the higher voltage levels of the synchronization signal and the lower threshold value is substantially an average of the lower voltage levels of the synchronization signal.

Moreover, owing that the video signal receiving apparatus 200 receives the composite signal by an alternative-current (AC)-coupling way, the invention fixes a direct-current (DC) voltage level of the composite signal by using the sync slicer 240 and the clamp circuit 250. The sync slicer 240 detects the pulse-edge of the synchronization signal of the luminance signal (Y) and accordingly outputs a clamp pulse cp. The clamp circuit 250 roughly fixes the voltage level of the synchronization signal in a specific range, such as between the high and low voltage levels H and L, according to the clamp pulse cp. In this way, the voltage level of the composite signal (synchronization signal) is fixed again and then transmitted to the ADC 210.

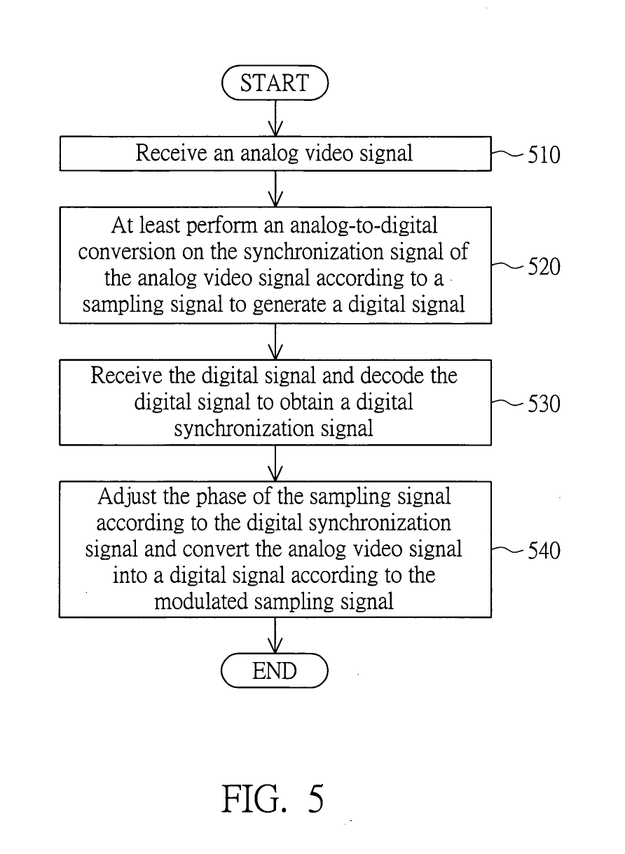

The invention further discloses a video-signal receiving method. Referring to FIG. 5, a flow chart of the video-signal receiving method according to the preferred embodiment of the invention is shown. First, in step 510, receive an analog video signal (luminance signal). The analog video signal includes a specific video signal and a synchronization signal. Next, in step 520, at least perform an analog-to-digital conversion on the synchronization signal of the analog video signal (luminance signal) according to a sampling signal so as to generate a digital signal. The frequency of the sampling signal is related to the frequency of the synchronization signal (the frequency of the sampling signal is roughly an integral multiplier of the frequency of the synchronization signal).

Following that, in step 530, receive the digital signal and decode the digital signal to obtain a digital synchronization signal corresponding to the synchronization signal. Then, in step 540, adjust the phase of the sampling signal according to the digital synchronization signal and convert the analog video signal into a digital signal according to the adjusted sampling signal.

The operational principle of the video-signal receiving method disclosed above has been described in illustration of the video-signal receiving apparatus 200, and thus any detail is not necessary to be given here.

The video-signal receiving apparatus and method disclosed by the above embodiment of the invention determines whether the phase of the sampling signal is a preferred phase according to the difference values between adjacent digital values of the digital synchronization signal and accordingly adjusts the phase of the sampling signal. Therefore, the analog video signal can be correctly converted into a digital signal according to the adjusted sampling signal to improve the display quality of video frames.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A video-signal receiving apparatus, comprising:
an analog-to-digital converter (ADC), for receiving an analog video signal, wherein the analog video signal comprises a specific video signal and a synchronization signal, and the ADC at least converts the synchronization signal of the analog video signal into a digital signal according to a sampling signal;
a digital image processor, coupled to the ADC, for receiving the digital signal and decoding the digital signal to obtain a digital synchronization signal corresponding to the synchronization signal; and
a phase adjustment device, coupled to the digital image processor and the ADC, for adjusting a phase of the sampling signal according to the digital synchronization signal.

2. The video-signal receiving apparatus according to claim 1, wherein the analog video signal complies with a specification of a composite signal.

3. The video-signal receiving apparatus according to claim 2, wherein the analog video signal is a luminance signal (Y).

4. The video-signal receiving apparatus according to claim 3, converting the luminance signal into a digital luminance signal according to the adjusted sampling signal.

5. The video-signal receiving apparatus according to claim 3, wherein the luminance signal corresponds to the specific video signal during a plurality of first periods and corresponds to the synchronization signal during a plurality of second periods, and at least one of the second periods is located between two adjacent first periods.

6. The video-signal receiving apparatus according to claim 5, wherein each of the second periods comprises a pre-equalization period, a broad-pulse period and a post-equalization period.

7. The video-signal receiving apparatus according to claim 1, wherein the phase adjustment device determines whether difference values between adjacent digital values of the digital synchronization signal are located between an upper threshold value and a lower threshold value, if yes, the phase adjustment device adjusts the phase of the sampling signal, and if no, the phase adjustment device maintains the phase of the sampling signal.

8. The video-signal receiving apparatus according to claim 7, further comprising:
a sync slicer, for detecting a pulse-edge of the synchronization signal in the analog video signal and accordingly outputting a clamp pulse; and
a clamp circuit, for adjusting the synchronization signal according to the clamp pulse such that a voltage level of the synchronization signal is roughly located in a specific range.

9. The video-signal receiving apparatus according to claim 7, wherein the upper threshold value corresponds to an average of a plurality of high voltage levels of the synchronization signal and the lower threshold value corresponds to an average of a plurality of low voltage levels of the synchronization signal.

10. The video-signal receiving apparatus according to claim 1, further receiving a chrominance signal and converting the chrominance signal into a digital chrominance signal according to the adjusted sampling signal.

11. The video-signal receiving apparatus according to claim 1, wherein the frequency of the sampling signal is related to the frequency of the synchronization signal.

12. The video-signal receiving apparatus according to claim 11, wherein the frequency of the sampling signal is an integral multiplier of the frequency of the synchronization signal.

13. The video-signal receiving apparatus according to claim 1, wherein the specific video signal corresponds to a piece of frame data.

14. A video-signal receiving method, comprising:
receiving an analog video signal, wherein the analog video signal comprises a specific video signal and a synchronization signal;
at least performing an analog-to-digital conversion on the synchronization signal of the analog video signal according to a sampling signal to generate a digital signal;
receiving the digital signal and decoding the digital signal to obtain a digital synchronization signal corresponding to the synchronization signal; and
adjusting a phase of the sampling signal according to the digital synchronization signal.

15. The video-signal receiving method according to claim 14, wherein the analog video signal complies with a specification of a composite signal.

16. The video-signal receiving method according to claim 15, wherein the analog video signal is a luminance signal.

17. The video-signal receiving method according to claim 16, further comprising:
converting the luminance signal into a digital luminance signal according to the adjusted sampling signal.

18. The video-signal receiving method according to claim 16, wherein the luminance signal corresponds to the specific video signal during a plurality of first periods and corresponds to the synchronization signal during a plurality of second periods, at least one of the second periods is located between two adjacent first periods.

19. The video-signal receiving method according to claim 18, wherein each of the second periods comprises a pre-equalization period, a broad-pulse period and a post-equalization period.

20. The video-signal receiving method according to claim 14, further comprising:
determining whether difference values between adjacent digital values of the digital synchronization signal are located between an upper threshold value and a lower threshold value;
if the difference values are located between the upper threshold value and the lower threshold value, adjusting the phase of the sampling signal; and
if the difference values are not located between the upper threshold value and the lower threshold value, maintaining the phase of the sampling signal.

21. The video-signal receiving method according to claim 20, further comprising:
detecting a pulse-edge of the synchronization signal in the analog video signal and accordingly outputting a clamp pulse; and
adjusting the synchronization signal according to the clamp pulse such that a voltage level of the synchronization signal is substantially located in a specific range.

22. The video-signal receiving method according to claim 20, wherein the upper threshold value corresponds to an average of a plurality of high voltage levels of the synchronization signal and the lower threshold value corresponds to an average of a plurality of low voltage levels of the synchronization signal.

23. The video-signal receiving method according to claim 14, further comprising:
receiving a chrominance signal and converting the chrominance signal into a digital chrominance signal according to the adjusted sampling signal.

24. The video-signal receiving method according to claim 14, wherein the frequency of the sampling signal is related to the frequency of the synchronization signal.

25. The video-signal receiving method according to claim 24, wherein the frequency of the sampling signal is an integral multiplier of the frequency of the synchronization signal.

26. The video-signal receiving method according to claim 14, wherein the specific video signal corresponds to a piece of frame data.
